(19) United States
(12) Patent Application Publication
(10) Pub. No.: US 2001/0009805 A1
(43) Pub. Date: Jul. 26, 2001

(54) Borderless contact structure and method of forming the same

(75) Inventors: Hoe-Seong Ha, Seoul (KR); Jun-Eui Song, Suwon (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-City (KR)

(21) Appl. No.: 09/765,543

(22) Filed: Jan. 19, 2001

(30) Foreign Application Priority Data
Jan. 21, 2000 (KR) 00-02901

(51) Int. Cl. H01L 29/76; H01L 31/113; H01L 29/94; H01L 31/062; H01L 31/119; H01L 21/76; H01L 23/58

(52) U.S. Cl. 438/637; 257/382; 438/424

(57) ABSTRACT

A borderless contact structure and method of forming thereof are provided. A device isolation region having a protrusion is formed at a predetermined region of a semiconductor substrate. The top surface of the protrusion is higher in level than that of the semiconductor substrate. An impurity diffusion region is formed in an active region surrounded by the device isolation region. An etch stop spacer is formed on a sidewall of the protrusion. An etch stop layer and an interlayer insulating layer are sequentially formed on the resultant structure including the impurity diffusion region, the device isolation region and the etch stop spacer. A contact hole opening the interlayer insulating layer and the etch stop layer is formed to expose at least a portion of the impurity diffusion region. Accordingly, during the etching process for forming the borderless contact hole exposing both the impurity diffusion region and the device isolation region adjacent to the impurity diffusion region, the device isolation region adjacent to the impurity diffusion region is not recessed, thereby improving leakage current characteristics of the semiconductor device.

This application relies for priority upon Korean Patent Application No. 2000-02901, filed on Jan. 21, 2000, the contents of which are herein incorporated by reference in their entirety.

### BACKGROUND OF THE INVENTION

1. Field of the Invention

The present invention relates to a contact structure in semiconductor device and method of forming the same and, more particularly, to a borderless contact structure and a method of forming the same.

2. Description of the Related Art

As the integration density of semiconductor device increases, the size of a contact hole becomes smaller. As a result, the contact resistance between conductive layers, which are electrically connected to each other via contacts, increases to degrade electrical characteristics of the semiconductor device.

Recently, a borderless contact hole formation technique has been proposed as an effort to minimize the contact resistance. The borderless contact hole exposes both a narrow active region and a device isolation region neighbouring the active region. However, the conventional borderless contact hole formation technique has a drawback of degrading contact leakage current characteristics due to a recessed device isolation region.

U.S. Pat. No. 5,677,231 issued to Papu D. et al. discloses a method of forming a borderless contact hole that can improve the contact leakage current characteristics in the presence of the recessed device isolation region. According to Papu D. et al., an aluminium nitride liner is interposed between a semiconductor substrate and a device isolation region filling a trench. Accordingly, sidewall of an impurity diffusion region, which is formed in the active region, is still covered by the liner during etching of an interlayer insulating layer to form a borderless contact hole exposing both the active region and the impurity diffusion region. However, it is preferable that a thermal oxide layer is formed at a bottom and sidewalls of the trench after formation of the trench in order to cure etch damage applied to the substrate during the formation of the trench via etching the substrate. Therefore, according to Papu D. et al., the thermal oxide layer interposed between the liner and the impurity diffusion region can be etched during the borderless contact hole formation, thereby exposing the sidewalls of the impurity diffusion region. This could lead to the degradation of leakage current characteristics of the semiconductor device.

Therefore, a need still remains to improve the borderless contact structure to address such problems.

### SUMMARY OF THE INVENTION

The present invention was made in view of above-mentioned problems and it is a feature of the present invention to provide a borderless contact structure, which improves contact leakage current characteristics.

It is another feature of the present invention to provide a borderless contact structure, improving a standby current characteristic.

It is still another feature of the present invention to provide a method of forming the borderless contact structure, improving the contact leakage current characteristic and the standby current characteristic.

These and other features of the present invention are achieved by a provision of the borderless contact structure. The borderless contact structure includes: a device isolation region formed in a predetermined portion of a semiconductor substrate, the device isolation region having a protrusion which is higher in level than a top surface of the semiconductor substrate; an impurity diffusion region formed in an active region surrounded by the device isolation region; an etch stop spacer formed on a sidewall of the protrusion; an etch stop layer and an interlayer insulating layer sequentially formed on the impurity diffusion region, the device isolation region and the etch stop spacer; and a contact hole opening the interlayer insulating layer and the etch stop layer. Herein the contact hole exposes at least a portion of the impurity diffusion region.

The device isolation region may be a trench isolation region.

Preferably, a thermal oxide layer is interposed between the device isolation region and the semiconductor substrate. Furthermore, a liner of a silicon nitride can be interposed between the thermal oxide layer and the device isolation region.

In addition, the contact hole may further expose the etch stop spacer adjacent to the exposed impurity diffusion region.

These and other features of the present invention are achieved by a method of forming a borderless contact structure. The method includes: forming a device isolation region at a predetermined region of a semiconductor substrate to define an active region, the device isolation region having a protrusion which is higher than a top surface of the semiconductor substrate; forming an etch stop spacer on a sidewall of the protrusion; sequentially forming an interlayer insulating layer and an etch stop layer on the semiconductor substrate having the etch stop spacer and the device isolation region; and patterning the interlayer insulating layer and the etch stop layer, thereby forming a contact hole exposing at least a portion of the active region.

The device isolation region is preferably formed by a trench isolation method.

It is preferable that the etch stop spacer is formed of silicon nitride or silicon oxynitride. It is also preferable that the etch stop layer is formed of silicon nitride or silicon oxynitride.

### BRIEF DESCRIPTION OF THE DRAWINGS

The above features and advantages of the invention will become apparent upon reference to the following detailed description of specific embodiments and the attached drawings, of which:

FIG. 1 is a cross-sectional view schematically showing a borderless contact structure in accordance with the present invention;

FIGS. 2 to 7 are cross-sectional views schematically showing a method of forming a borderless contact structure at selected stages in accordance with the present invention;

FIG. 8a is a graph showing the contact resistance and the contact leakage current of various borderless contact structures according to the present invention;

FIG. 8b is a top plan view for explaining the overlap distance (OD) of FIG. 8a;

FIG. 9 is a graph showing the contact leakage current characteristics of N+ borderless contact structures according to the present invention and the prior art;

FIG. 10 is a graph showing the contact leakage current characteristics of P+ borderless contact structures according to the present invention and the prior art; and

FIG. 11 is a graph showing standby current characteristics per 1 megabit cells of an 8 megabit SRAM adopting the borderless contact structures according to the present invention and the prior art.

### DETAILED DESCRIPTION OF THE PREFERRED EMBODIMENTS

The preferred embodiment of the present invention will now be described with reference to the accompanying drawings.

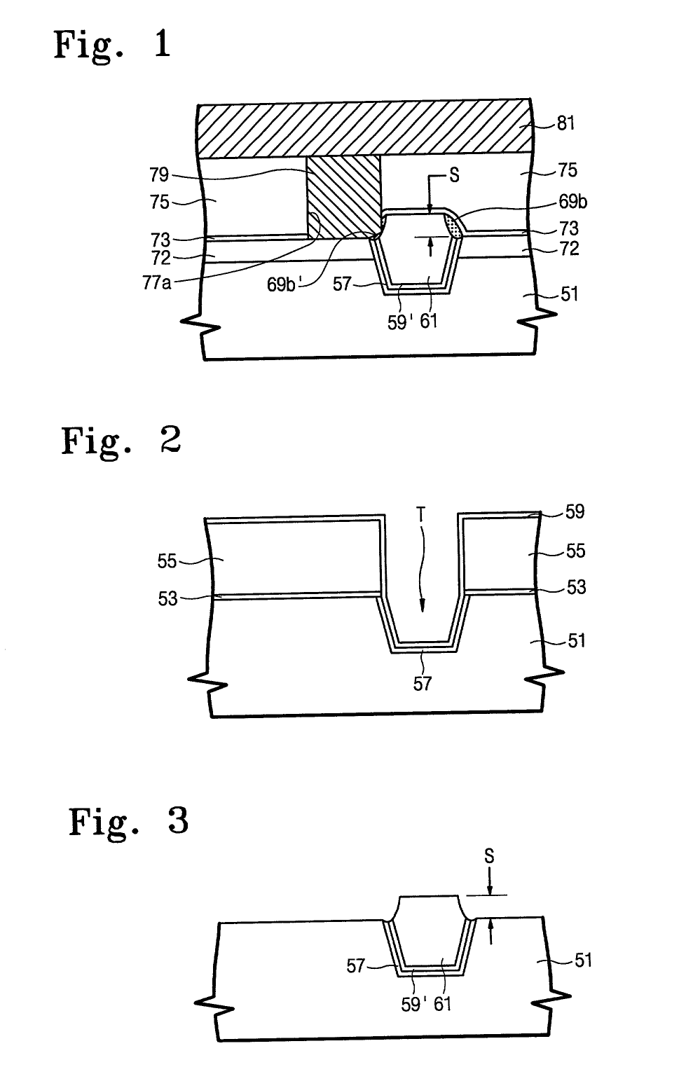

First, a borderless contact structure according to the present invention will be described with reference to FIG. 1.

Referring to FIG. 1, a device isolation region 61 such as a trench isolation region is disposed in a predetermined region of a semiconductor substrate 51. The device isolation region 61 can be formed of an insulating material such as a CVD (chemical vapor deposition) oxide layer, and has a protrusion that is higher than the top surface of the semiconductor substrate 51. It is preferable that the step difference S between the semiconductor substrate 51 and the device isolation region 61 is at least 300 angstroms. It is also preferable that a thermal oxide layer 57 is interposed between the substrate 51 and the device isolation region 61. Furthermore, a silicon nitride liner 59′ is preferably interposed between the thermal oxide layer 57 and the device isolation region 61. Sidewall of the protrusion is covered with an etch stop spacer 69b.

An impurity diffusion region 72 having a predetermined depth is formed at an active region that corresponds to a surface of the semiconductor substrate 51 adjacent to the device isolation region 61. The impurity diffusion region 72 is doped with impurities having a different conductivity type compared to that of the semiconductor substrate. An etch stop layer 73 and an interlayer insulating layer 75 are sequentially stacked on the resultant structure comprising the impurity diffusion region 72, the etch stop spacer 69b and the device isolation region 61. A contact hole 77a opening the interlayer insulating layer 75 and the etch stop layer 73 exposes the impurity diffusion region 72 and the etch stop spacer 69b′ adjacent to the impurity diffusion 72. Herein, the etch stop spacer 69b′ exposed by the contact hole 77a may be a small-sized and transformed etch stop spacer as compared to the initial etch stop spacer 69b, as shown in FIG. 1. Even after formation of the contact hole 77a, the transformed etch stop spacer 69b′ covers at least the interface region between the device isolation region 61 and the impurity diffusion region 72 adjacent to the device isolation region 61. Namely, during the formation of the contact hole 77a, the etch stop spacer 69b protects the interface region, thereby preventing the edge portion of the device isolation region 61 adjacent to the impurity diffusion region 72 from being recessed.

The contact hole 77a is filled with a contact plug 79 being in contact with the impurity diffusion region 72 and the transformed etch stop spacer 69b′ adjacent to the impurity diffusion region 72. An interconnection line 81 overlies the contact plug 79.

As described above, the borderless contact structure includes the etch stop spacer on the sidewall of the protrusion of the device isolation region. Accordingly, during the etching process for forming the borderless contact hole exposing both the impurity diffusion region and the device isolation region adjacent to the impurity diffusion region, the device isolation region adjacent to the impurity diffusion region is not recessed.

A method of forming the borderless contact hole structure of FIG. 1 will now be described with reference to FIGS. 2 to 7.

Referring now to FIG. 2, a pad oxide layer 53 and a pad nitride layer 55 are sequentially formed on a semiconductor substrate 51 such as a silicon substrate. The pad oxide layer 53 serves as a buffer layer for alleviating the stress due to the thermal expansion coefficient difference between the substrate 51 and the pad nitride layer 55. Preferably, the pad oxide layer 53 is formed to a thickness of approximately 200 angstroms or less and the pad nitride layer 55 is formed to a thickness of approximately 1,500 angstroms or more. The pad nitride layer 55 and the pad oxide layer 53 are sequentially patterned to expose a predetermined region of the semiconductor substrate 51. The exposed region of the semiconductor substrate 51 is then etched to form a trench region T.

The substrate having the trench region T is thermally oxidized to form a thermal oxide layer 57 on a sidewall and a bottom of the trench region T. The thermal oxide layer 57 is preferably formed to a thickness of approximately 100 angstroms or less. The thermal oxidation process is performed in order to cure etching damage on the substrate 51 during the etching process for forming the trench region T. A silicon nitride layer 59 can be further formed on the resultant structure including the thermal oxide layer 57. The silicon nitride layer 59 is preferably formed to a thickness of approximately100 angstroms or less. The silicon nitride layer 59 serves as a diffusion barrier layer for preventing impurities in a trench isolation region from being diffused into the substrate 51 in a subsequent process. The silicon nitride layer 59 also suppresses the oxidation of the trench sidewall during a subsequent annealing process.

Referring to FIG. 3, the substrate having the trench region T is covered with an insulating layer filling the trench region T. The insulating layer can be formed of a CVD oxide layer. The insulating layer is then planarized until the pad nitride layer 55 is exposed, thereby forming an insulating layer pattern within the trench region T. The exposed silicon nitride layer 55 is removed by using an etchant such as a phosphoric acid (H3PO4). At this time, a silicon nitride liner 59′ remains on the bottom and sidewall of the trench region T. The pad oxide layer 53 is then removed by using an oxide etchant such as hydrofluoric acid (HF) or buffered oxide etchant (BOE). The portion of the insulating layer pattern is also etched. As a result, a device isolation region 61 filling the trench region T is completed.

It should be noted that the device isolation region 61 is formed to have a top surface higher in level than a top surface of the semiconductor substrate 51. Particularly, the step difference S between the top surface of the device isolation 61 and the top surface of the semiconductor substrate 51 is approximately 300 angstroms or more. Preferably, the step difference S is approximately 500 angstroms. As mentioned above, the device isolation region 61 should have a protrusion from the top surface of the semiconductor substrate 51.

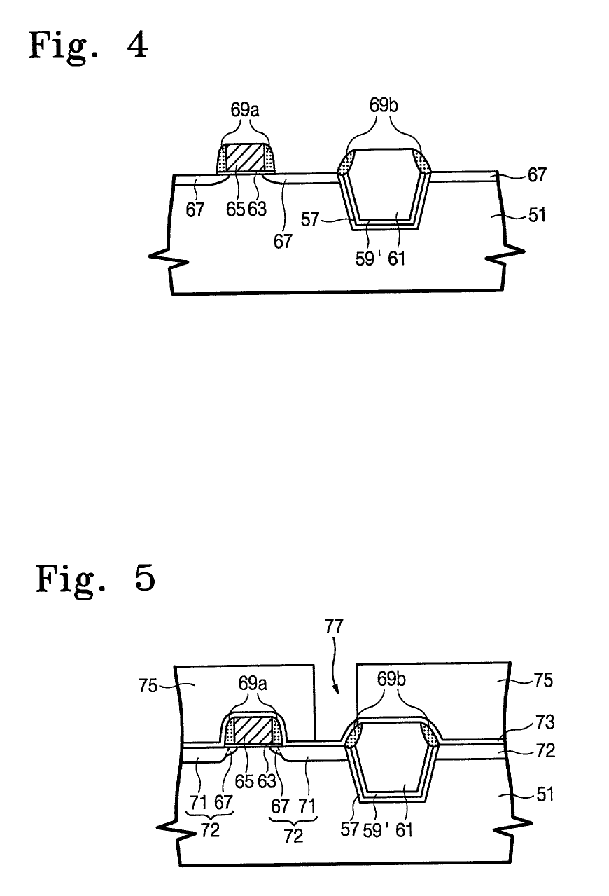

Referring to FIG. 4, a gate insulating layer 63, a conductive layer and a capping layer are sequentially formed on the semiconductor substrate including the device isolation layer 61. The capping layer and the conductive layer are sequentially patterned to form a gate pattern 65. Alternatively, the process for forming the capping layer can be omitted. In this case, the gate pattern 65 corresponds to a gate electrode made of only the conductive layer. Using the gate pattern 65 and the device isolation region 61 as implanting masks, impurity ions are implanted into the semiconductor substrate 51 at a low dose of approximately 1×1012 to 1×1014 atoms/cm2, thereby forming an lightly doped drain (LDD) region 67. The conductivity type of the impurity ions is different from that of the semiconductor substrate 51.

Subsequently, an insulating layer for forming a spacer is formed on the resultant structure having the LDD region 67. The insulating layer for forming a spacer is preferably formed of a silicon nitride layer or a silicon oxynitride layer. The insulating layer for forming a spacer is formed to a thickness of approximately 1,200 angstroms. Anisotropic etching is carried out on the insulating layer for forming a spacer, thereby forming a gate spacer 69a and an etch stop spacer 69b on a sidewall of the gate pattern 65 and on a sidewall of the protrusion of the device isolation region 61, respectively.

Referring to FIG. 5, using the gate spacer 69a, the etch stop spacer 69b, the gate pattern 65 and the device isolation region 61 as implanting masks, impurity ions are implanted into the semiconductor substrate 51 at a high dose of approximately 1×1015 to 5×1015 atoms/cm2, thereby forming a high concentration impurity diffusion region 71. The conductivity type of impurity ions for forming the high concentration impurity diffusion region 71 is the same as the conductivity type of the LDD region 67. As a result, a portion of the LDD region 67 exists under the gate spacer 69a. The LDD region 67 and the high concentration impurity diffusion region 71 constitute an impurity diffusion region 72 that acts as a source/drain region of MOS transistor.

An etch stop layer 73 and an interlayer insulating layer 75 are sequentially formed on the resultant structure having the impurity diffusion region 72. The interlayer insulating layer 75 is formed of an insulating layer such as a silicon oxide layer. Preferably, the etch stop layer 73 is formed of an insulating material having an etching selectivity with respect to the interlayer insulating layer 75. For example, the etch stop layer 73 may be formed of a silicon nitride layer or a silicon oxynitride layer. Herein, the etch stop layer 73 is formed to a thickness of approximately 300 angstroms to 500 angstroms. The interlayer insulating layer 75 is then patterned to form a hole 77 exposing a region of the etch stop layer 73.

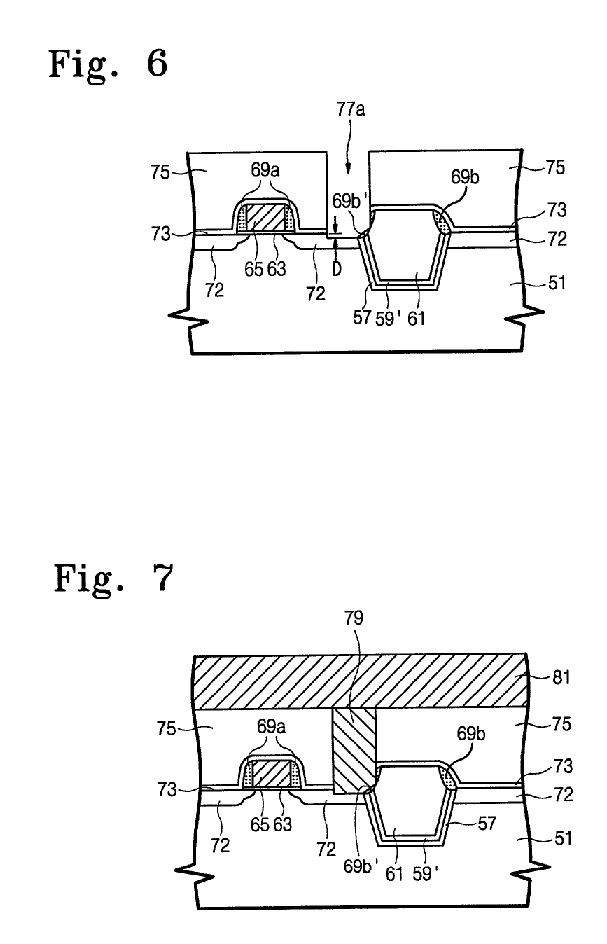

Referring to FIG. 6, the etch stop layer 73 exposed by the hole 77 is etched to form a borderless contact hole 77a exposing a region of the impurity diffusion region 72 and the etch stop spacer 69b adjacent to the impurity diffusion region 72. At this time, over-etching is carried out on the etching stop layer 73 in order to completely expose substantially all of the impurity diffusion regions 72 formed throughout the semiconductor substrate 51. As a result, not only the impurity diffusion region 72 is recessed by a predetermined depth “D” but also the exposed etch stop spacer 69b is partially etched. Thus, a transformed (partially etched) etch stop spacer 69b′ remains at the bottom of the borderless contact hole 77a. Accordingly, due to the etch stop spacer 69b, the edge portion of the device isolation region 61 adjacent to the impurity diffusion region 72 is not recessed.

Though not shown in the drawings, if the borderless contact hole 77a exposes not only the edge portion of the device isolation region 61 but also a center portion thereof, the center portion of the device isolation region 61 can be recessed. However, in this case, the edge portion of the device isolation region 61 is not recessed due to the etch stop spacer 69b. Accordingly, the sidewall of the impurity diffusion region 72 is almost always covered with the thermal oxide layer 57 or the device isolation region 61, even though the borderless contact hole 77a is overlapped with the device isolation region 61.

Referring to FIG. 7, a contact plug 79 is formed in the borderless contact hole 77a with a conductive material such as tungsten. A metal layer is formed on the resultant structure having the contact plug 79. The metal layer is then patterned to form an interconnection line 81 to be interconnected with the contact plug 79.

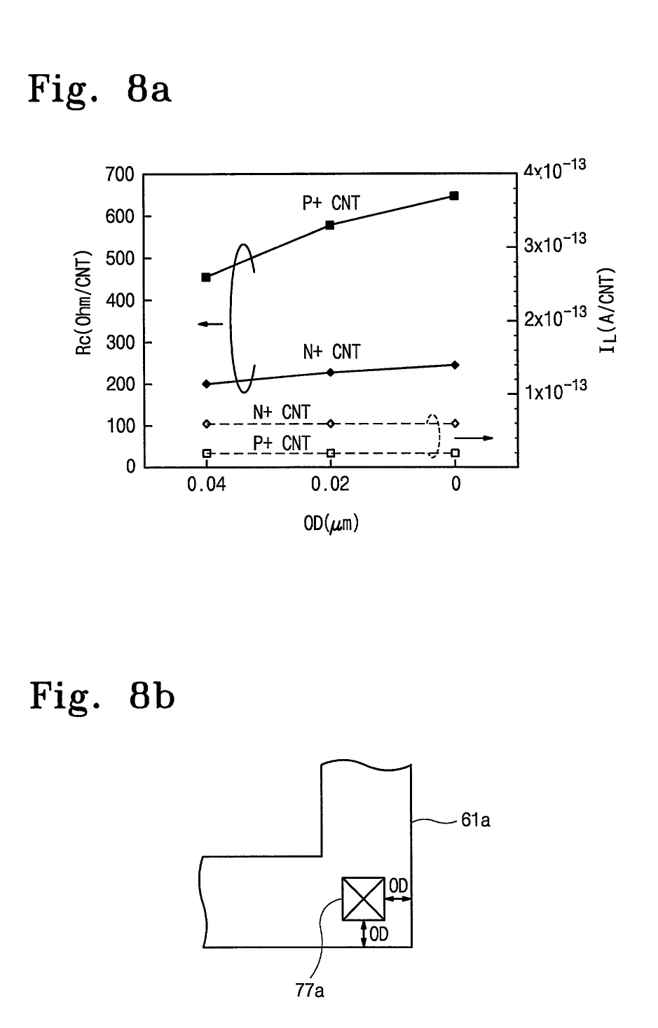

FIG. 8a is a graph showing the contact resistance (Rc) and the contact leakage current (IL) of various borderless contact structures according to the present invention, and FIG. 8b is a top plan view for illustrating an overlap distance (OD) of FIG. 8a. In FIG. 8a, a horizontal axis represents the OD between the contact hole and the active region, and a left-side vertical axis represents contact resistance (RC), and right-side vertical axis represents a leakage current (IL). In FIG. 8b, reference numeral 61a represents an active region and the reference numeral 77a represents a contact hole exposing the active region 61a. The device isolation region defining the active region 61a was formed by a trench isolation technique. The step difference S between the top surfaces of the device isolation region and the active region was approximately 500 angstroms. The size of the contact hole 77a was 0.18 micrometers× 0.18 micrometers. Also, N+ impurity diffusion region was formed by implanting arsenic (As) ions with a dose of approximately 3×105 atoms/cm2 at an energy of approximately 40 KeV and P+ impurity diffusion region was formed by implanting boron fluoride (BF2) ions with a dose of approximately 2×105 atoms/cm2 at an energy of approximately 25 KeV.

Referring again to FIG. 8a, the contact structures according to the present invention exhibit a stable contact leakage current (IL) regardless of the OD. In particular, in case of N+ contact structure, the contact leakage current (IL) was maintained at a unique value of approximately 0.6×10-13 (Ampere) even though the OD was changed from 0.04 micrometers to 0 micrometer. Likewise, the contact leakage current (IL) of P+ contact structure was maintained at a unique value of approximately 0.2×10-13 (Ampere) even though the OD was changed from 0.04 micrometers to 0 micrometer. However, the contact resistance (RC) of the N+ contact structure exhibits a tendency to increase, i.e., from 200 ohms/one contact to 260 ohms/one contact, as the OD has been decreased from 0.04 micrometers to 0 micrometer. Likewise, the contact resistance (RC) of the P+ contact structure exhibits a tendency to increase, i.e., from 450 ohms to 650 ohms, as the OD has been decreased from 0.04 micrometers to 0 micrometer. This is because the exposed area of the impurity diffusion region becomes smaller and smaller as the OD has been decreased from 0.04 micrometers to 0 micrometer. The contact leakage current value was measured under the reverse bias of 2.6 V and at a temperature of approximately 85° C.

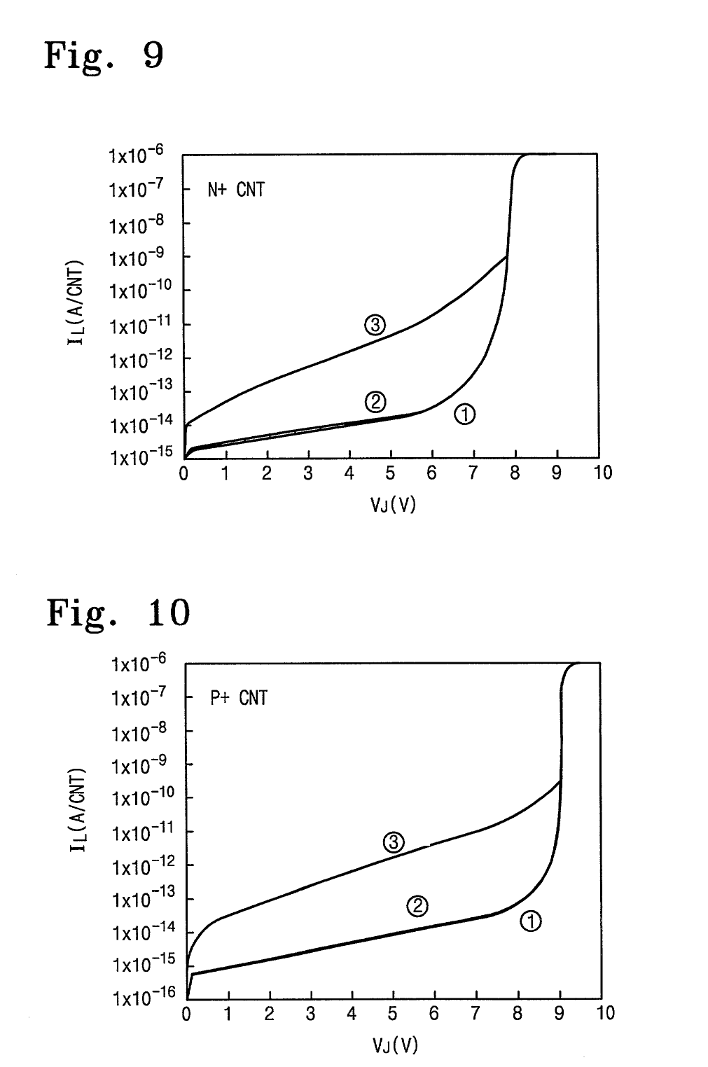

FIGS. 9 and 10 are graphs showing the contact leakage current characteristics of N+ and P+ contact structures, respectively. Here, the horizontal axes in FIGS. 9 and 10 represent a reverse bias voltage (VJ) applied to the N+ and P+ junctions. Also, the vertical axes in FIGS. 9 and 10 represent a leakage current (IL). In FIGS. 9 and 10, curves 1 and 3 correspond to the prior art and curve 2 corresponds to the present invention. In detail, curve 1 indicates the contact leakage current characteristic of the prior art having the OD of 0.06 micrometers, curve 3 indicates the contact leakage current characteristic of the prior art having the OD of 0 micrometer. On the contrary, curve 2 indicates the contact leakage current characteristic of the present invention having the OD of 0 micrometer. It is to be noted that the prior art does not include the etch stop layer of the present invention.

As can be seen in FIGS. 9 and 10, the contact leakage current of the present invention having the OD of 0 micrometer was almost equal to that of the prior art having the OD of 0.06 micrometers. On the contrary, the contact leakage current of the prior art having the OD of 0 micrometer was much higher than that of the present invention having the OD of 0 micrometer. Herein, the contact leakage current was measured at a temperature of approximately 85° C. as like in FIG. 8a.

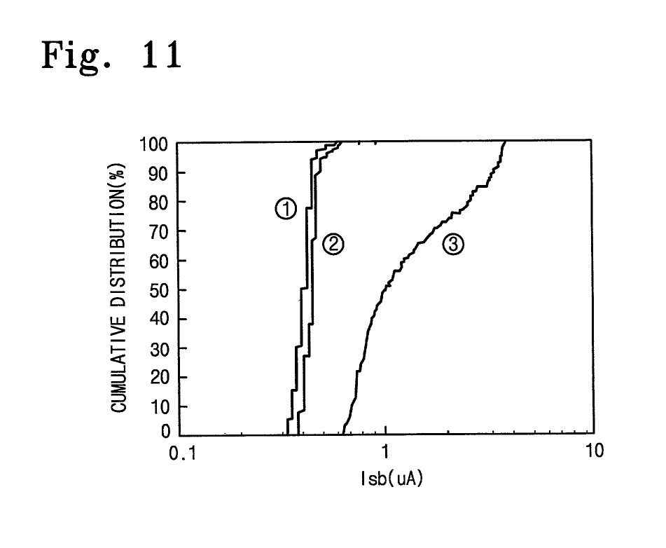

FIG. 11 is a graph showing a standby current characteristic per 1 megabit cells of an 8 megabit SRAM device adopting the contact structure according to the present invention and the prior art. Herein, the 8 megabit SRAM device was fabricated using the full CMOS cell technology. In FIG. 11, horizontal axis represents standby current (Isb), and the vertical axis represents cumulative distribution of the standby current (Isb). The standby current (Isb) represents the current flowing through 1 megabit SRAM cells and was measured at a temperature of approximately 85° C. The contact structures of the present invention and the prior art were applied to the node contacts of the full CMOS SRAM cell.

More particularly, curve 1 shows the standby current characteristic of the prior art having the OD of 0.06 micrometers and curve 3 shows the standby current characteristic of the prior art having the OD of 0 micrometer. Curve 2 shows the standby current characteristic of the present invention having the OD of 0 micrometer.

As can be seen in FIG. 11, the standby current values (Isb) of the sample devices (OD=0 micrometer) according to the present invention were distributed in the range of 0.3 microamperes to 0.7 microamperes. Also, the standby current values (Isb) of the sample devices (OD=0.06 micrometers) according to the prior art were distributed in the same range as that of the present invention. On the contrary, the standby current values (Isb) of the sample devices (OD=0 micrometer) according to the prior art were distributed in the wide range of 0.7 microamperes to 3.5 microamperes.

As described above, the present invention provides novel borderless contact structure that can improve significantly the characteristics of the contact leakage current as compared to the prior art. Furthermore, when the borderless contact structure of the present invention is applied to the node contact of memory devices such as SRAM, integration density of SRAM can be increased and also the standby current characteristics can be improved.

Having illustrated and described the principles of my invention in a preferred embodiment thereof, it should be readily apparent to those skilled in the art that the invention can be modified in arrangement and detail without departing from such principles. We claim all modifications coming within the spirit and scope of the accompanying claims.

What is claimed is:

1. A borderless contact structure comprising:
a semiconductor substrate having a top surface;
a device isolation region formed in a predetermined region of the semiconductor substrate, the device isolation region having a protrusion that is higher in level than the top surface of the semiconductor substrate;
an impurity diffusion region formed in an active region surrounded by the device isolation region;
an etch stop spacer formed overlying a sidewall of the protrusion;
an etch stop layer and an interlayer insulating layer sequentially formed over the resultant structure; and
a contact hole opening the interlayer insulating layer and the etch stop layer, the contact hole exposing at least a portion of the impurity diffusion region.

2. The borderless contact structure according to claim 1, wherein the etch stop spacer is partially etched.

3. The borderless contact structure according to claim 1, wherein the device isolation region comprises a trench isolation region.

4. The borderless contact structure according to claim 3, further comprising a thermal oxide layer interposed between the semiconductor substrate and the trench isolation region.

5. The borderless contact structure according to claim 4, further comprising a silicon nitride liner interposed between the trench isolation region and the thermal oxide layer.

6. The borderless contact structure according to claim 1, wherein the etch stop spacer comprises silicon nitride or silicon oxynitride.

7. The borderless contact structure according to claim 1, wherein the etch stop layer comprises silicon nitride or silicon oxynitride.

8. The borderless contact structure according to claim 1, further comprising an interconnection line filling the contact hole.

9. The borderless contact structure according to claim 1, further comprising:
a contact plug filling the contact hole; and
an interconnection line overlying the contact plug.

10. The borderless contact structure according to claim 1, wherein the contact hole exposes not only the impurity diffusion region but also a portion of the etch stop spacer adjacent to the exposed impurity diffusion region.

11. A method of forming a borderless contact structure, the method comprising:
selectively etching a predetermined portion of a semiconductor substrate to form a trench defining an active region having a top surface;
forming a device isolation region in the trench, the device isolation region having a protrusion which is higher in level than the top surface of the active region;
forming an etch stop spacer on a sidewall of the protrusion;
forming an impurity diffusion region in the active region;
sequentially forming an etch stop layer and an interlayer insulating layer over the resultant structure; and
successively patterning the interlayer insulating layer and the etch stop layer to form a contact hole exposing at least a portion of the impurity diffusion region.

12. The method according to claim 11, wherein the step of forming an etch stop spacer comprises:
forming a gate pattern on the active region;
forming a lightly doped drain (LDD) region in the active region at both sides of the gate pattern;
forming an insulating layer for for forming a spacer on the resultant structure including the LDD region, the insulating layer for forming a spacer being formed of a material having an etching selectivity with respect to the interlayer insulating layer; and
anisotropic etching the insulating layer for forming a spacer to form a gate spacer on a sidewall of the gate pattern and to form the etch stop spacer on the sidewall of the protrusion of the device isolation region.

13. The method according to claim 11, wherein the etch stop spacer is made of silicon nitride or silicon oxynitride.

14. The method according to claim 11, wherein the etch stop layer is made of silicon nitride or silicon oxynitride.

15. The method according to claim 11, further comprising:
forming a contact plug in the contact hole; and
forming an interconnection line overlying the contact plug.

16. The method according to claim 11, wherein the contact hole exposes both the impurity diffusion region and the portion of the etch stop spacer adjacent to the exposed impurity diffusion region.

17. The method according to claim 11, wherein the etch stop spacer is partially etched.
